(19) United States
(12) Patent Application Publication
(10) Pub. No.: US 2010/0315763 A1
(43) Pub. Date: Dec. 16, 2010

(54) Shock Isolation System for a Mobile Unit with a Monocoque Housing

(76) Inventors: Carl Thelemann, East Islip, NY (US); Timothy Austin, Stony Brook, NY (US); Thomas Wulff, North Patchogue, NY (US)

Correspondence Address: MOTOROLA, INC., 1303 EAST ALGONQUIN ROAD, IL01/3RD, SCHAUMBURG, IL, 60196, US

(21) Appl. No.: 12/481,984

(22) Filed: Jun. 10, 2009

(51) Int. Cl. H05K 5/00

(52) U.S. Cl. 361/679.01

(57) ABSTRACT

A monocoque housing for a mobile unit comprises a base, an end cap, and an isolation gasket. The mobile unit includes an electronic stack assembly. The base has an opening. The end cap is adapted to removably couple with the base. The end cap includes a cap and a frame where the frame is received by the base through the opening so that the cap covers the opening. The isolation gasket is disposed between the frame and the electronic stack assembly. The electronic stack assembly is not mechanically fastened to the isolation gasket. When the mobile unit experiences a shock load, the isolation gasket absorbs the shock load to reduce the shock load on the electronic stack assembly.

### FIELD OF THE INVENTION

The present invention relates generally to a shock isolation system for a mobile unit with a monocoque housing. Specifically, and end cap of the monocoque housing includes the shock isolation system so internal circuitry is not required to be hard mounted.

### BACKGROUND

A mobile unit may be designed using a variety of configurations. In a first example, the mobile unit may include several plates that, when assembled, constitutes an overall housing. Due to the multiple components that are included for this configuration, the mobile unit may be susceptible to an increased number of problems. In a second example, the mobile unit may include a monocoque housing with a main housing body and an end cap. Internal circuitry may be disposed within the main housing body with the end cap completing the overall housing of the mobile unit.

Conventionally, a mobile unit with a monocoque housing has the internal electronic stack hard mounted (e.g., via screws) to both the monocoque housing and the end cap. With the internal electronic stack hard mounted to the housing, energy from a shock load (e.g., drop, bang, etc.) is transmitted directly from the housing to the internal electronic stack. The internal electronic stack may include fragile components such as a scanning engine, a camera, a liquid crystal display, etc. For low drop heights (e.g., under four feet), it may be acceptable to hard mount the internal electronic stack because the energy levels associated with a shock load may be within an acceptable range that significant damage is not experienced. However, when the shock load is increased (e.g., greater than four feet), the internal stack may suffer irreparable damage.

### SUMMARY OF THE INVENTION

The present invention describes a monocoque housing for a mobile unit. The mobile unit includes an electronic stack assembly. The monocoque housing comprises a base, an end cap, and an isolation gasket. The base has an opening. The end cap is adapted to removably couple with the base. The end cap includes a cap and a frame where the frame is received by the base through the opening so that the cap covers the opening. The isolation gasket is disposed between the frame and the electronic stack assembly. The electronic stack assembly is not mechanically fastened to the isolation gasket. When the mobile unit experiences a shock load, the isolation gasket absorbs the shock load to reduce the shock load on the electronic stack assembly.

### DESCRIPTION OF THE DRAWINGS

FIG. 1 shows a first exploded view of a mobile unit according to an exemplary embodiment of the present invention.

FIG. 2 shows a second exploded view of the mobile unit of FIG. 1 according to an exemplary embodiment of the present invention.

### DETAILED DESCRIPTION

The exemplary embodiments of the present invention may be further understood with reference to the following description and the appended drawings, wherein like elements are referred to with the same reference numerals. The exemplary embodiments of the present invention describe a shock isolation system for a mobile unit (MU) with a monocoque housing. According to the exemplary embodiments of the present invention, the monocoque housing may include a base housing (i.e., main body housing), an end cap, and an isolation gasket. The base housing, the end cap, and the isolation gasket will be discussed in further detail below.

It should be noted that the MU may represent any mobile electronic device that uses a monocoque housing. As an electronic device, the MU may have an electronic stack assembly that is configured for the functionalities that the MU may perform. The MU may include, for example, a laptop, a pager, a cell phone, a radio frequency identification device, a scanner, a data acquisition device and/or an imager, a multi-media device, etc. Thus, the electronic stack assembly may include corresponding devices that facilitate the functionalities for the above listed types of MUs.

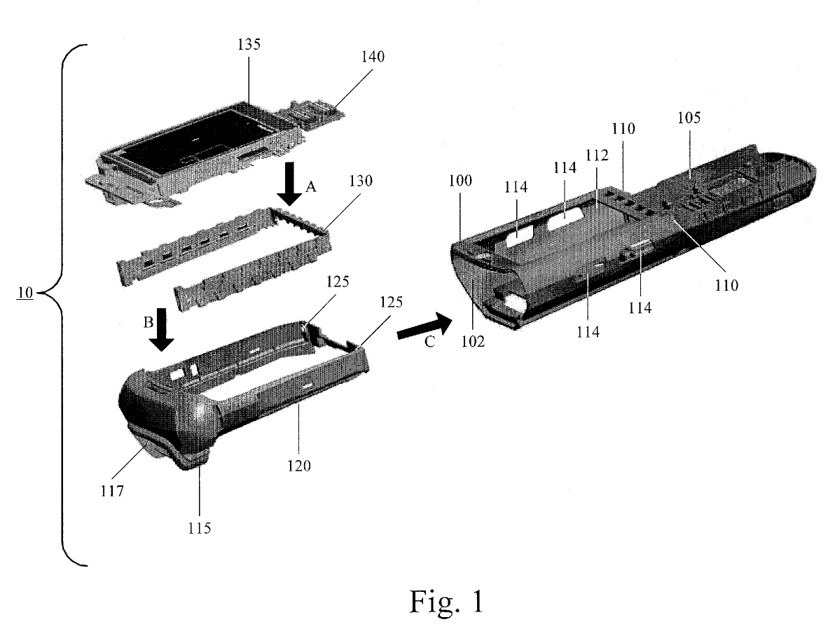

FIG. 1 shows a first exploded view of a MU 10 according to an exemplary embodiment of the present invention. The first exploded view further illustrates a first perspective view for assembling the monocoque housing of the MU 10. As illustrated, the monocoque housing comprises a base housing 100, an end cap 115, and an isolation gasket 130.

The MU 10 may include an electronic stack assembly 135 which may include electronic components of the MU 10. For example, the electronic stack assembly 135 may include printed circuit board (PCB) assemblies and further include ball grid array (BGA) components, a scan engine, a camera, a liquid crystal display (LCD), etc. The electronic stack assembly 135 may further include a connector 140 which may couple to additional electronic components that may be disposed on the base housing 100 such as a data input arrangement.

The base housing 100 may be configured to house various components of the MU 10. As will be described in further detail below, the base housing 100 may include a space 112 in which the electronic stack assembly 135 is received. An inner surface of the base housing 100 may be premolded to exhibit a shape that corresponds to the electronic stack assembly 135. Furthermore, the base housing 100 may include further components that connect to the electronic stack assembly 135. For example, the MU 10 may include a data input arrangement such as a key pad that is disposed in an area 105 of the base housing 100. The base housing 100 may include an opening 102 in which the electronic stack assembly may slide therein. The base housing 100 may further include additional windows 114 in which components of the electronic stack assembly 135 require to be disposed on a periphery of the monocoque housing. For example, the base housing 100 may include a further window in which the LCD may be exposed. In another example, the base housing may include further windows in which side data input arrangements may be exposed. Accordingly, when the electronic stack assembly 135 is received by the base housing 100, a proper reception of the electronic stack assembly 135 ensures that such components are configured in a proper orientation.

The base housing 100 may include locking mechanisms 110. According to the exemplary embodiments of the present invention, the locking mechanisms 110 may be disposed on the base housing 100 in a position that contacts a portion of the end cap 115. Specifically, the portion of the end cap 115 may include corresponding locking mechanisms to the locking mechanisms 110. The types and configurations for the locking mechanisms 110 will be described in further detail below.

The end cap 115 may be a complimentary component to the base housing 100 for the overall monocoque housing of the MU. The end cap 115 may include a cap 117 and a frame 120. The cap 117 may cover the opening 102 of the base housing 100. The frame 120 may be configured to receive the isolation gasket 130. For example, the frame 120 may be configured to receive the isolation gasket 130 without a mechanism to lock therein. In another example, the frame 120 may be lined with locking mechanisms in which the isolation gasket 130 is disposed.

As discussed above, the frame 120 may include corresponding locking mechanisms 125 that couple to the locking mechanisms 110 of the base housing 100. According to an exemplary embodiment of the present invention, the locking mechanisms 110 may be screw holes that align with corresponding locking mechanisms 125 which are further screw holes. Screws (not shown) may be threaded therethrough to couple the end cap 115 with the base housing 100. It should be noted that any locking feature such as a mechanical or electronic may be used to couple the end cap 115 with the base housing 100. Accordingly, the locking mechanisms 110 and the corresponding locking mechanisms 125 may correlate to components of the locking feature.

The isolation gasket 130 may provide a site for the electronic stack assembly 135 to be disposed without being required to be hard mounted thereon. The isolation gasket 130 may be configured to removably receive the electronic stack assembly 135. In such an embodiment, the isolation gasket 130 may be shaped to correspond to the electronic stack assembly 135. For example, an inner region of the isolation gasket 130 may correspond to an outer perimeter of the electronic stack assembly 135. When the MU 10 is properly assembled, the isolation gasket 130 may be disposed between the frame 120 and the electronic stack assembly 135.

The isolation gasket 130 may further provide a shock diminishing or prevention to the electronic stack assembly 135 when the monocoque housing is assembled with the electronic stack assembly 135. The isolation gasket 130 may be manufactured using a variety of materials that contribute to the shock isolation. For example, the isolation gasket 130 may be manufactured using a thermoplastic polyurethane (TPU), a thermoplastic elastomer (TPE), a thermoplastic silicate (TPSI), a rubber, a combination thereof, etc. The material used to manufacture the isolation gasket 130 may, for example, absorb a shock experienced by the MU 10. The isolation gasket 130 may also be arranged to prevent a shock from the frame 115 reaching the electronic stack assembly 135 such as by the shape exhibited by the isolation gasket 130. The isolation gasket 130 may also be shaped to provide a substantially spring-like movement which absorbs a shock and also prevents the shock from reaching the electronic stack assembly 135.

According to the exemplary embodiments of the present invention, as illustrated, the electronic stack assembly 135 may be disposed on or in the isolation gasket 130 by placement along a direction A. The electronic stack assembly 135 with the isolation gasket 130 may be disposed on the frame 120 of the end cap 115 by placement along a direction B. Subsequently, the end cap 115 with the isolation gasket 130 and the electronic stack assembly 135 may be coupled with the base housing 100 to complete the monocoque housing of the MU 10 by placement along a direction C through the window 102 of the base housing 100. Upon the base housing 100 receiving the end cap 115, the locking mechanisms 110 and the corresponding locking mechanisms 125 may couple to securely fasten the end cap 115 with the base housing 100.

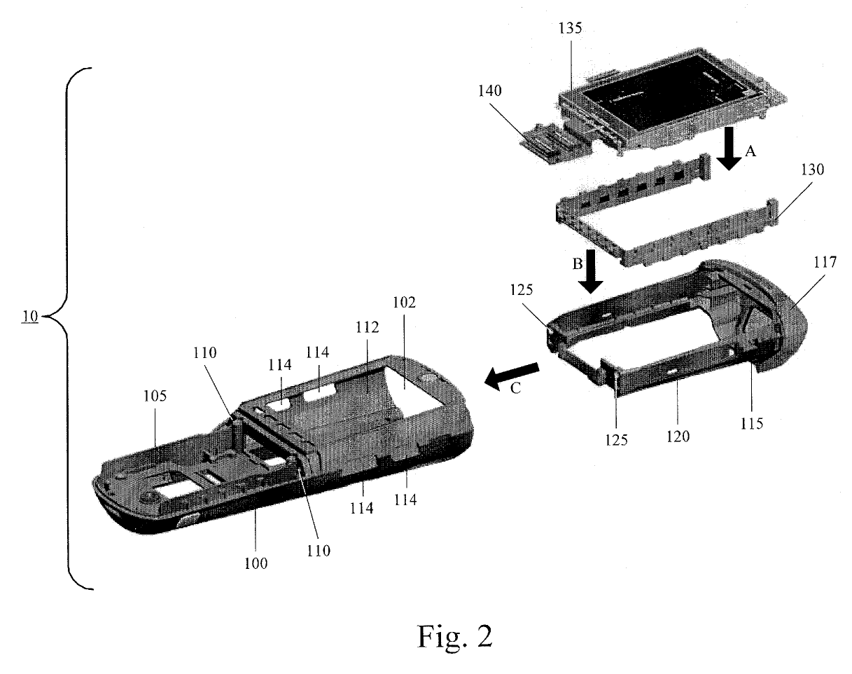

FIG. 2 shows a second exploded view of the MU 10 of FIG. 1 according to an exemplary embodiment of the present invention. The second exploded view further illustrates a second perspective view for assembling the monocoque housing of the MU 10. Specifically, the second perspective view is an opposite perspective for assembling the monocoque housing and better illustrates the locking mechanisms 110. That is, when the monocoque housing is assembled and the locking feature is screw holes, the second exploded view shows how the potential alignment of the locking mechanisms 110 with the corresponding locking mechanisms 125.

It should be noted that the isolation gasket 130 being provided for the shock diminishing and/or prevention is only exemplary. According to the exemplary embodiments of the present invention, the isolation gasket 130 may represent any component providing a buffer to diminish or prevent a shock load that is disposed between the frame 120 of the end cap 115 and the electronic stack assembly 135.

The exemplary embodiments of the present invention provide for a monocoque housing of a mobile unit that enables an electronic stack assembly to be housed therein without a need to hard mount to any component of the monocoque housing. As a result, the electronic stack assembly may not be disposed in a position where, if a shock load is experienced by the mobile unit, the shock load is transferred directly to the electronic stack assembly which may irreparably damage a component thereon. The electronic stack assembly may be mounted on an isolation gasket or other component that reduces the shock load that would be experienced by the electronic stack assembly.

It will be apparent to those skilled in the art that various modifications may be made in the present invention, without departing from the spirit or scope of the invention. Thus, it is intended that the present invention cover the modifications and variations of this invention provided they come within the scope of the appended claims and their equivalents.

What is claimed is:

1. A monocoque housing of a mobile unit, the mobile unit including an electronic stack assembly, the monocoque housing comprising:
a base having an opening;
an end cap adapted to removably couple with the base, the end cap including a cap and a frame, the frame being received by the base through the opening so that the cap covers the opening; and
an isolation gasket disposed between the frame and the electronic stack assembly, the electronic stack assembly not mechanically fastened to the isolation gasket,
wherein, when the mobile unit experiences a shock load, the isolation gasket absorbs the shock load to reduce the shock load on the electronic stack assembly.

2. The monocoque housing of claim 1, wherein the base includes further components that couple to the electronic stack assembly.

3. The monocoque housing of claim 2, wherein one of the further components is a data input arrangement.

4. The monocoque housing of claim 1, wherein the base includes at least one further window for a component of the electronic stack assembly to be on a periphery of the housing.

5. The monocoque housing of claim 4, wherein the component is a display.

6. The monocoque housing of claim 1, wherein the base includes a locking mechanism to secure the end cap upon assembly.

7. The monocoque housing of claim 6, wherein the frame of the end cap includes a corresponding locking mechanism which couples to the locking mechanism.

8. The monocoque housing of claim 1, wherein the isolation gasket is one of securely and removably disposed one of on and in the frame.

9. The monocoque housing of claim 1, wherein the isolation gasket is made with one of a thermoplastic polyurethane (TPU), a thermoplastic elastomer (TPE), a thermoplastic silicate (TPSI), a rubber, and a combination thereof.

10. The monocoque housing of claim 1, wherein the isolation gasket one of absorbs at least a portion of the shock load and prevents at least a portion of the shock load from reaching the electronic stack assembly.

11. An end cap for a monocoque housing of a mobile unit, the mobile unit including an electronic stack assembly, the end cap comprising:
a cap;
a frame extending from the cap, the frame being received by a base of the monocoque housing through an opening of the base so that the cap covers the opening,
wherein the frame is disposed in the base so that an isolation gasket is disposed between the frame and the electronic stack assembly, the electronic stack assembly not mechanically fastened to the isolation gasket,
wherein, when the mobile unit experiences a shock load, the isolation gasket absorbs the shock load to reduce the shock load on the electronic stack assembly.

12. The end cap of claim 11, wherein the frame is received in the base in a proper orientation so that further components disposed in the base couple to the electronic stack assembly.

13. The end cap of claim 12, wherein one of the further components is a data input arrangement.

14. The end cap of claim 11, wherein the frame is received in the base in a proper orientation so that select components of the electronic stack assembly are disposed on a periphery of the base through at least one further window of the base.

15. The end cap of claim 14, wherein one of the select components is a display.

16. The end cap of claim 11, further comprising:
a locking mechanism disposed on an end of the frame to secure the end cap with the base.

17. The end cap of claim 11, wherein the frame one of securely and removably receives the isolation gasket one of thereon and therein.

18. The end cap of claim 11, wherein the isolation gasket is made with one of a TPU, a TPE, a TPSI, a rubber, and a combination thereof.

19. The end cap of claim 11, wherein the frame receives the isolation gasket so that the isolation gasket one of absorbs at least a portion of the shock load and prevents at least a portion of the shock load from reaching the electronic stack assembly.

20. A monocoque housing of a mobile unit, the mobile unit including an electronic stack assembly, the monocoque housing comprising:
a base having an opening;
an end cap adapted to removably couple with the base, the end cap including a cap and a frame, the frame being received by the base through the opening so that the cap covers the opening; and
an absorbing means for absorbing a shock load experienced by the mobile unit to reduce the shock load on the electronic stack assembly, the absorbing means being disposed between the frame and the electronic stack assembly, the electronic stack assembly not mechanically fastened to the absorbing means.
